(19) United States
(12) Patent Application Publication
(10) Pub. No.: US 2022/0195591 A1
(43) Pub. Date: Jun. 23, 2022

(54) SURFACE TREATMENT AGENT, SURFACE TREATMENT METHOD, AND REGION SELECTIVE FILM FORMATION METHOD FOR SURFACE OF SUBSTRATE

(71) Applicant: TOKYO OHKA KOGYO CO., LTD., Kawasaki-shi (JP)

(72) Inventors: Kenji SEKI, Kawasaki-shi (JP); Jun IIOKA, Kawasaki-shi (JP); Taiji NAKAMURA, Kawasaki-shi (JP)

(21) Appl. No.: 17/644,670

(22) Filed: Dec. 16, 2021

(30) Foreign Application Priority Data
Dec. 23, 2020 (JP) 2020-214226

(51) Int. Cl. C23C 16/02; C07F 9/38; C23C 16/455

(52) U.S. Cl. CPC C23C 16/0272; C23C 16/45536; C07F 9/3808

(57) ABSTRACT

A surface treatment agent used for treating a substrate having a surface that has two or more regions made of different materials, in which at least one of the two or more regions has a metal surface, and pretreated with an oxidizing agent, the agent including a compound (P) represented by R¹—P(═O)(OR²)(OR³), and an organic solvent (S) having a relative dielectric constant of 35 or less. In the formula, R¹ represents an alkyl group or the like, and R² and R³ represent a hydrogen atom or an alkyl group.

### BACKGROUND OF THE INVENTION

### Field of the Invention

The present invention relates to a surface treatment agent, a surface treatment method, and a region selective film formation method for a surface of a substrate.

Priority is claimed on Japanese Patent Application No. 2020-214226, filed Dec. 23, 2020, the content of which is incorporated herein by reference.

### Description of Related Art

In recent years, with the progress of high integration and miniaturization of semiconductor devices, miniaturization of organic patterns used as masks and inorganic patterns prepared by etching treatments has proceeded, and thus the film thickness needs to be controlled at an atomic layer level.

As a method of forming a film, which is thin at an atomic layer level, on a substrate, an atomic layer deposition method (ALD; hereinafter, also simply referred to as an “ALD method”) is known. The ALD method is known to have both high step coverage and film thickness controllability as compared with a typical chemical vapor deposition (CVD) method.

The ALD method is a thin-film forming technique of alternately supplying two kinds of gases having elements constituting a film intended to be formed as main components onto a substrate and repeatedly forming a thin film a plurality of times on the substrate in an atomic layer unit to form a film having a desired thickness.

In the ALD method, a self-control function (self-limit function) of growth in which only one layer or several layers of raw material gas components are adsorbed on a surface of a substrate while the raw material gases are supplied and the extra raw material gases do not contribute to the growth is used.

For example, in a case where an Al₂O₃ film is formed on a substrate, a raw material gas formed of trimethyl aluminum (TMA) and an oxidizing gas containing O are used. Further, in a case where a nitride film is formed on a substrate, a nitride gas is used in place of the oxidizing gas.

In recent years, a region selective film formation method for a surface of a substrate using the ALD method has been attempted (see J. Phys. Chem. C 2014, 118, pp. 10957 to 10962 and ACS NANO Vol. 9, No. 9, pp. 8710 to 8717 (2015)).

Along with such attempts, there has been a demand for a substrate having a region-selectively modified surface so that the substrate can be suitably applied to a region selective film formation method for a substrate according to the ALD method.

In the film formation method, control of the film thickness at an atomic layer level, step coverage, and miniaturization of patterning are expected by using the ALD method.

### CITATION LIST

### Non Patent Documents

[Non Patent Document 1] J. Phys. Chem. C 2014, 118, pp. 10957 to 10962
[Non Patent Document 2] ACS NANO Vol. 9, No. 9, pp. 8710 to 8717 (2015)

### SUMMARY OF THE INVENTION

However, the methods described in J. Phys. Chem. C 2014, 118, pp. 10957 to 10962 and ACS NANO Vol. 9, No. 9, pp. 8710 to 8717 (2015) have a problem in that since the surface of a substrate is region-selectively modified, the surface modification takes a long time depending on the kind of the substrate.

The present invention has been made in consideration of the above-described circumstances, and an object thereof is to provide a surface treatment method carried out using a surface treatment agent capable of shortening the treatment time, and a region selective film formation method for a surface of a substrate to which the surface treatment method has been applied, in a method of treating a substrate which has a surface having two or more regions made of materials that are different from each other.

In order to solve the above-described problems, the present invention has adopted the following configurations.

According to a first aspect of the present invention, there is provided a surface treatment agent used for treating a substrate having a surface that has two or more regions made of different materials, in which at least one of the two or more regions has a metal surface, and pretreated with an oxidizing agent, the agent including: a compound (P) represented by Formula (P-1); and an organic solvent (S) having a relative dielectric constant of 35 or less.

R¹—P(═O)(OR²)(OR³) (P-1)

[In the formula, R¹ represents a linear or branched alkyl group, a linear or branched fluorinated alkyl group, or an aromatic hydrocarbon group which may have a substituent. R² and R³ each independently represent a hydrogen atom, a linear or branched alkyl group, a linear or branched fluorinated alkyl group, or an aromatic hydrocarbon group which may have a substituent.]

A second aspect of the present invention, there is provided a surface treatment method for a substrate having a surface that has two or more regions made of different materials, in which at least one region of the two or more regions has a metal surface, the method including: performing a pretreatment on the surface with an oxidizing agent; and exposing the surface to the surface treatment agent according to the first aspect.

According to a third aspect of the present invention, there is provided a region selective film formation method for a surface of a substrate, the method including: treating the surface of the substrate using the surface treatment method according to the second aspect; and forming a film on the surface of the substrate, which has been subjected to the surface treatment, using an atomic layer deposition method, in which an amount of a material of the film to be deposited region-selectively varies.

According to the present invention, it is possible to provide a surface treatment method carried out using a surface treatment agent capable of shortening the treatment time, and a region selective film formation method for a surface of a substrate to which the surface treatment method has been applied, in a method of treating a substrate which has a surface having two or more regions made of materials that are different from each other.

### BRIEF DESCRIPTION OF THE DRAWINGS

FIG. 1 shows XPS analysis results of a substrate after being subjected to a surface treatment of each test example.

### DETAILED DESCRIPTION OF THE INVENTION

### First Embodiment: Surface Treatment Agent

A surface treatment agent according to a first embodiment of the present invention is a surface treatment agent used for treating a substrate pretreated with an oxidizing agent, which has a surface having two or more regions, at least one of which has a metal surface and in which proximity regions from among the two or more regions are made of different materials (hereinafter, also simply referred to as a “surface to be treated”).

The surface to be treated to which the surface treatment agent according to the present embodiment is applied has two or more regions, at least one of which has a metal surface, proximity regions among the two or more regions are made of different materials.

In the present embodiment, in a case where the surface to be treated has two regions, the surface to be treated has a first region having a metal surface and a second region that is made of a material different from that of the first region and is adjacent to the first region. In such a case, the “proximity regions” are the first region and the second region.

Here, each of the first region and the second region may or may not be divided into a plurality of regions.

In the present embodiment, in a case where the surface to be treated has three or more regions, the surface to be treated has a first region having a metal surface, a second region that is made of a material different from that of the first region and is adjacent to the first region, and a third region that is made of a material different from that of the second region and is adjacent to the second region. In such a case, the “proximity regions” may be the first region and the second region (that is, the adjacent regions) or the first region and the third region (that is, the regions separated by a region).

Further, in a case where the first region and the third region are made of different materials (that is, both the first region and the third region have a metal surface), the “proximity regions” are the first region and the second region, or the second region and the third region (that is, adjacent regions).

Here, each of the first region, the second region, and the third region may or may not be divided into a plurality of regions.

In the present embodiment, the same idea can be applied to a case where the surface to be treated has the fourth or more regions.

The upper limit of the number of regions made of different materials is not particularly limited as long as the effects of the present invention are not impaired, and the upper limit thereof is, for example, 7 or less or 6 or less and typically 5 or less.

In the present embodiment, the metal surface contained in the surface to be treated is not particularly limited, and examples thereof include a metal surface containing at least one selected from the group consisting of tungsten, ruthenium, copper, and cobalt and a metal surface containing at least one selected from the group consisting of tungsten and ruthenium.

In the present embodiment, the surface to be treated is pretreated with an oxidizing agent.

The oxidizing agent for pretreating the surface to be treated (hereinafter, also referred to as an “oxidizing agent for a pretreatment”) is not particularly limited as long as a natural oxide film present on the surface to be treated can be removed and a hydroxyl group can be imparted to the surface to be treated. Specific examples of the oxidizing agent for a pretreatment include a peroxide such as hydrogen peroxide, perhalogen acid such as periodic acid, and oxo acid such as nitric acid or hypochlorous acid. Among these, from the viewpoint of improving water repellency of the surface to be treated, at least one selected from the group consisting of hydrogen peroxide and perhalogen acid is preferable as the oxidizing agent for a pretreatment. Further, it is preferable that at least one selected from the group consisting of hydrogen peroxide and perhalogen acid is used in combination with an inorganic substance such as SiO₂ and Al₂O₃ from the viewpoint of treating the metal surface without damaging the inorganic substance.

In the present embodiment, the oxidizing agent for a pretreatment may be used alone or in combination of two or more kinds thereof.

The surface treatment agent of the present embodiment contains a compound (P) represented by Formula (P-1) and an organic solvent (S) having a relative dielectric constant of 35 or less.

R¹—P(═O)(OR²)(OR³) (P-1)

[In the formula, R¹ represents a linear or branched alkyl group, a linear or branched fluorinated alkyl group, or an aromatic hydrocarbon group which may have a substituent. R² and R³ each independently represent a hydrogen atom, a linear or branched alkyl group, a linear or branched fluorinated alkyl group, or an aromatic hydrocarbon group which may have a substituent.]

Compound (P)

The compound (P) is phosphonic acid represented by Formula (P-1) or a derivative thereof.

In Formula (P-1), R¹ represents a linear or branched alkyl group, a linear or branched fluorinated alkyl group, or an aromatic hydrocarbon group which may have a substituent.

In Formula (P-1), the linear or branched alkyl group as R¹ has preferably 1 to 45 carbon atoms, more preferably 5 to 40 carbon atoms, and still more preferably 8 to 35 carbon atoms.

Specific examples of the linear or branched alkyl group as R¹ include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group, a docosyl group, and isomers of the above-described alkyl groups.

In Formula (P-1), as the linear or branched fluorinated alkyl group as R′, a group in which some or all hydrogen atoms of the linear or branched alkyl group have been substituted with fluorine atoms is an exemplary example.

In Formula (P-1), examples of the aromatic hydrocarbon group which may have a substituent as R¹ include a phenyl group, a naphthyl group, an anthryl group, a p-methylphenyl group, a p-tert-butylphenyl group, a p-adamantylphenyl group, a tolyl group, a xylyl group, a cumenyl group, a mesityl group, a biphenyl group, a phenanthryl group, a 2,6-diethylphenyl group, and a 2-methyl-6-ethylphenyl group.

Among these, R¹ represents preferably a linear or branched alkyl group having 8 or more carbon atoms and more preferably a dodecyl group or an octadecyl group.

Examples of the linear or branched alkyl group, the linear or branched fluorinated alkyl group, or the aromatic hydrocarbon group which may have a substituent as R² and R³ are the same as those for the linear or branched alkyl group, the linear or branched fluorinated alkyl group, or the aromatic hydrocarbon group which may have a substituent as R′.

Among these, it is preferable that R² and R³ represent a hydrogen atom.

In the present embodiment, the compound (P) may be used alone or in combination of two or more kinds thereof.

In the surface treatment agent according to the present embodiment, the content of the compound (P) is preferably in a range of 0.0001 to 5% by mass, more preferably in a range of 0.001 to 4% by mass, still more preferably in a range of 0.005 to 3% by mass, and even still more preferably in a range of 0.008 to 3% by mass with respect to the total mass of the surface treatment agent.

In a case where the content of the compound (P) is in the above-described preferable range, the compound (P) is likely to be adsorbed on the region having the metal surface, and the selectivity of the surface treatment agent for the region having the metal surface is likely to be improved.

Organic Solvent (S)

The organic solvent (S) is not particularly limited as long as the organic solvent has a relative dielectric constant of 35 or less, and examples thereof include methanol (relative dielectric constant: 33), diethylene glycol monobutyl ether (BDG) (relative dielectric constant: 13.70), propylene glycol monomethyl ether (PE) (relative dielectric constant: 12.71), benzyl alcohol (relative dielectric constant: 12.70), 2-heptanone (relative dielectric constant: 11.74), butyl glycol acetate (relative dielectric constant: 8.66), tert-butyl alcohol (relative dielectric constant: 12.5), 1-octanol (relative dielectric constant: 10.21), isobutanol (relative dielectric constant: 18.22), benzotrifluoride (relative dielectric constant: 9.18), decahydronaphthalene (relative dielectric constant: 2.16), cyclohexane (relative dielectric constant: 1.99), decane (relative dielectric constant: less than 1), isobutyl alcohol (relative dielectric constant: 18.22), ethyl lactate (EL) (relative dielectric constant: 13.22), diethylene glycol monomethyl ether (relative dielectric constant: 15.76), 1-nonanol (relative dielectric constant: 9.13), toluene (relative dielectric constant: 2.37), propylene glycol monomethyl ether acetate (PM) (relative dielectric constant: 9.4), methylisobutylcarbinol (MIBC) (relative dielectric constant: 10.47), 2,6-dimethyl-4-heptanol (relative dielectric constant: 2.98), 2-ethyl-1-butanol (relative dielectric constant: 12.6), 2-butanone oxime (relative dielectric constant: 2.9), n-dibutyl ether (relative dielectric constant: 3.33), butylate butyrate (relative dielectric constant: 4.55), and 2,6-dimethyl-4-heptanone (relative dielectric constant: 9.82).

Among these, as the organic solvent (S), at least one selected from the group consisting of methanol (relative dielectric constant: 33), diethylene glycol monobutyl ether (BDG) (relative dielectric constant: 13.70), polyethylene glycol (PE) (relative dielectric constant: 12.71), benzyl alcohol (relative dielectric constant: 12.70), 2-heptanone (relative dielectric constant: 11.74), butyl glycol acetate (relative dielectric constant: 8.66), tert-butyl alcohol (relative dielectric constant: 12.5), 1-octanol (relative dielectric constant: 10.21), and isobutanol (relative dielectric constant: 18.22) is preferable, and at least one selected from the group consisting of benzyl alcohol (relative dielectric constant: 12.70) and isobutanol (relative dielectric constant: 18.22) is more preferable.

Further, the Hansen solubility parameter (dP) of the organic solvent (S) is preferably 0 or greater and less than 16, more preferably in a range of 0 to 15, and still more preferably in a range of 0 to 14.

In a case where the Hansen solubility parameter (dP) of the organic solvent (S) is in the above-described preferable range, the water repellency of the metal surface is likely to be enhanced.

In the present embodiment, the organic solvent (S) may be used alone or in combination of two or more kinds thereof.

Further, the relative dielectric constant of the organic solvent (S) can be measured using a commercially available liquid dielectric constant measuring device (for example, “Rufuto Model 871” manufactured by Nihon Rufuto Co., Ltd.) or the like.

Water

The surface treatment agent according to the present embodiment may contain water in order to further improve the water repellency and improve the contact angle. Water may contain a trace amount of components that are inevitably mixed. As the water used for the surface treatment agent according to the present embodiment, it is preferable to use water that has been subjected to a purification treatment such as distilled water, ion exchange water, or ultrapure water and more preferable to use ultrapure water typically used for manufacture of semiconductors.

In the surface treatment agent according to the present embodiment, the content of water in a case where the surface treatment agent contains water is preferably in a range of 0.01% to 25% by mass, more preferably in a range of 0.03% to 20% by mass, and still more preferably in a range of 0.05% to 15% by mass.

In a case where the content of water is in the above-described preferable range, the compound (P) is likely to be adsorbed on the region having the metal surface, and the selectivity of the surface treatment agent for the region having the metal surface is likely to be improved. Further, the water repellency of the surface treatment agent is more likely to be improved, and the contact angle is likely to be improved.

The surface treatment agent of the present embodiment contains a compound (P) represented by Formula (P-1) and an organic solvent (S) having a relative dielectric constant of 35 or less.

The compound (P) is phosphonic acid or a derivative thereof. In the compound (P), the phosphonic acid moiety [—P(═O)(OR²)(OR³)] is hydrophilic and the alkyl chain moiety (R¹) is hydrophobic. Therefore, in a method of treating a surface which has two or more regions and in which adjacent regions from among the two or more regions are made of different materials, the phosphonic acid moiety of the compound (P) functions as an adsorption group, and the alkyl chain moiety thereof functions as a water repellent group. Therefore, the compound (P) functions as a material (hereinafter, referred to as a “SAM agent”) for forming a self-assembled monolayer.

In addition, the organic solvent (S) has a relative dielectric constant of 35 or less and a low polarity. Therefore, in the compound (P) of the organic solvent (S), the reactivity only in the phosphonic acid moiety is increased, and the adsorptive power to the metal surface is enhanced.

Further, the surface treatment agent of the present embodiment is applied to the surface to be treated which has been pretreated with the oxidizing agent for a pretreatment. In the surface to be treated, a natural oxide film or the like on the metal surface is removed by the pretreatment, and a hydroxyl group is imparted thereto.

Combined with the above effects, it is presumed that the surface treatment agent of the present embodiment can shorten the treatment time in the method of treating a substrate having a surface that has two or more regions made of different materials.

Further, since the surface treatment agent according to the present embodiment has a high selectivity (particularly) for a region having a metal surface, the surface treatment agent can be suitably applied particularly to the region selective film formation method for a surface of a substrate using the ALD method.

### Second Embodiment: Surface Treatment Method

A surface treatment method according to a second embodiment of the present invention is a surface treatment method for a substrate having a surface that has two or more regions made of different materials, in which at least one region of the two or more regions has a metal surface, the method including performing a pretreatment on the surface with an oxidizing agent, and exposing the pretreated surface to the surface treatment agent according to the first embodiment.

In the surface treatment method according to the present embodiment, the surface has two or more regions, and the contact angles in proximity regions in the two or more regions made of different materials are made to be different from each other by reacting the compound (P) with the two or more regions.

In the surface treatment method according to the second embodiment, the surface of the substrate has two or more regions, at least one of the two or more regions has a metal surface, and proximity regions in the two or more regions are made of different materials.

Among the above-described two or more regions, examples of the region in which the contact angle of water tends to be higher (preferably, the surface free energy decreases) than other regions include regions containing at least one selected from the group consisting of tungsten (W), cobalt (Co), aluminum (Al), aluminum oxide (Al₂O₃), titanium nitride (TiN), tantalum nitride (TaN), nickel (Ni), ruthenium (Ru), and copper (Cu). Among these, a region containing at least one selected from the group consisting of tungsten, ruthenium, copper, and cobalt is preferable, and a region containing at least one selected from the group consisting of tungsten and ruthenium is more preferable.

Among the two or more regions, examples of the regions in which the contact angle of water tends to be smaller (preferably, the surface free energy increases) than other regions include regions containing at least one selected from the group consisting of silicon (Si), silicon nitride (SiN), a silicon oxide film (Ox), germanium (Ge), silicon germanium (SiGe), tetraethoxysilane (TEOS), a Low-k material, and an interlayer insulating film (ILD).

The “surface of a substrate” may indicate a surface of an inorganic pattern or an organic pattern provided on a substrate, a surface of an unpatterned inorganic layer or an unpatterned organic layer provided on a substrate, or the like, in addition to a surface of a substrate itself.

Examples of the inorganic pattern provided on a substrate include a pattern formed by etching a surface of an inorganic layer present on a substrate according to a photoresist method to prepare a mask and performing an etching treatment thereon. Examples of the inorganic layer include an oxide film of an element constituting a substrate; and a film or a layer of an inorganic substance such as SiN, Ox, W, Co, TiN, TaN, Ge, SiGe, Al, Al₂O₃, Ni, Ru, Cu, tetraethoxysilane (TEOS), a Low-k material, or an interlayer insulating film (ILD) formed on a surface of a substrate, in addition to a substrate itself.

Such a film or layer is not particularly limited, and examples thereof include a film or a layer of an inorganic substance formed in the process of preparation of a semiconductor device.

Examples of the organic pattern provided on a substrate include a resin pattern formed on a substrate using a photoresist or the like according to a photolithography method. Such an organic pattern can be formed by, for example, forming an organic layer which is a photoresist film on a substrate, exposing the organic layer through a photomask, and developing the organic layer. The organic layer may be an organic layer provided on a surface of a laminated film provided on a surface of a substrate in addition to a surface of a substrate itself. Such an organic layer is not particularly limited, and examples thereof include a film of an organic substance provided to form a mask by performing etching in the process of preparation of a semiconductor device.

In the present embodiment, the surface of the substrate has a first region having a metal surface and a second region that is made of a material different from that of the first region and is adjacent to the first region. In such a case, the “proximity regions” are the first region and the second region.

Here, each of the first region and the second region may or may not be divided into a plurality of regions.

Examples of the first region and the second region include an embodiment in which the surface of the substrate itself is set as the first region and a surface of an inorganic layer formed on the surface of the substrate is set as the second region and an embodiment in which a surface of a first inorganic layer formed on the surface of the substrate is set as the first region and a surface of a second inorganic layer formed on the surface of the substrate is set as the second region. Further, an embodiment in which an organic layer is formed in place of the formation of these inorganic layers can also be an exemplary example.

As the embodiment in which the surface of the substrate itself is set as the first region and a surface of an inorganic layer formed on the surface of the substrate is set as the second region, from the viewpoint of selectively improving the hydrophobicity to improve a difference in contact angle of water between two or more regions adjacent to each other and made of different materials on the surface of the substrate, an embodiment in which a surface of at least one substrate selected from the group consisting of a Si substrate, a SiN substrate, an Ox substrate, a TiN substrate, a TaN substrate, a Ge substrate, a SiGe substrate, TEOS, a Low-K material, and ILD is set as the first region and a surface of an inorganic layer which is formed on the surface of the substrate and contains at least one selected from the group consisting of W, Co, Al, Ni, Ru, and Cu is set as the second region is preferable.

Further, as the embodiment in which a surface of a first inorganic layer formed on the surface of the substrate is set as the first region and a surface of a second inorganic layer formed on the surface of the substrate is set as the second region, from the viewpoint of selectively improving the hydrophobicity to improve a difference in contact angle of water between two or more regions adjacent to each other and made of different materials on the surface of the substrate, an embodiment in which a surface of a first inorganic layer which is formed on a surface of an optional substrate (for example, a Si substrate) and contains at least one selected from the group consisting of SiN, Ox, TiN, TaN, Ge, SiGe, TEOS, a Low-k material, and ILD is set as the first region and a surface of a second inorganic layer which is formed on the surface of the substrate and contains at least one selected from the group consisting of W, Co, Al, Ni, Ru, and Cu is set as the second region is preferable.

(Embodiment in which Surface of Substrate has Three or More Regions)

In the present embodiment, in a case where the surface of the substrate has three or more regions, the surface of the substrate has a first region having a metal surface, a second region that is made of a material different from that of the first region and is adjacent to the first region, and a third region that is made of a material different from that of the second region and is adjacent to the second region. In such a case, the “proximity regions” may be the first region and the second region (that is, the adjacent regions) or the first region and the third region (that is, the regions separated by a region).

Further, in a case where the first region and the third region are made of different materials (that is, both the first region and the third region have a metal surface), the “proximity regions” are the first region and the second region, or the second region and the third region (that is, adjacent regions).

Here, each of the first region, the second region, and the third region may or may not be divided into a plurality of regions.

Examples of the first region, the second region, and the third region include an embodiment in which the surface of the substrate itself is set as the first region, a surface of a first inorganic layer formed on the surface of the substrate is set as the second region, and a surface of a second inorganic layer formed on the surface of the substrate is set as the third region. Further, an embodiment in which an organic layer is formed in place of the formation of these inorganic layers can also be an exemplary example. Further, an embodiment including both an inorganic layer and an organic layer formed by changing only one of a second inorganic layer and a third inorganic layer to an organic layer can also be an exemplary example.

From the viewpoint of selectively improving the hydrophobicity to improve a difference in contact angle of water between two or more regions adjacent to each other and made of different materials on the surface of the substrate, an embodiment in which a surface of an optional substrate (for example, a Si substrate) is set as the first region, a surface of a first inorganic layer which is formed on the surface of the substrate and contains at least one selected from the group consisting of SiN, Ox, TiN, TaN, Ge, SiGe, TEOS, a Low-k material, and ILD is set as the second region, and a surface of a second inorganic layer which is formed on the surface of the substrate and contains at least one selected from the group consisting of W, Co, Al, Ni, Ru, and Cu is set as the third region is preferable.

In the present embodiment, the same idea can be applied to a case where the surface of the substrate has the fourth or more regions.

The upper limit of the number of regions made of different materials is not particularly limited as long as the effects of the present invention are not impaired, and the upper limit thereof is, for example, 7 or less or 6 or less and typically 5 or less.

(Pretreatment)

In the present embodiment, the oxidizing agent for pretreating the surface to be treated (oxidizing agent for a pretreatment) is the same as the oxidizing agent for a pretreatment in the first embodiment. Among these, from the viewpoint of improving water repellency of the surface to be treated, at least one selected from the group consisting of hydrogen peroxide and perhalogen acid is preferable as the oxidizing agent for a pretreatment. Further, it is preferable that at least one selected from the group consisting of hydrogen peroxide and perhalogen acid coexist with a metal oxide such as SiO₂ or Al₂O₃ on the surface to be treated from the viewpoint of not damaging the metal oxide.

In the present embodiment, the treatment temperature of the pretreatment is not particularly limited, but is typically in a range of 10° C. to 35° C., preferably in a range of 15° C. to 30° C., and more preferably in a range of 20° C. to 25° C.

In a case where the treatment temperature of the pretreatment is in the above-described preferable range, the natural oxide film on the metal surface is easily removed, and a hydroxyl group is easily imparted to the metal surface.

Further, in the present embodiment, the treatment time of the pretreatment is not particularly limited, but is typically in a range of 10 seconds to 10 minutes, preferably in a range of 20 seconds to 5 minutes, and more preferably in a range of 30 seconds to 3 minutes.

In a case where the treatment temperature of the pretreatment is in the above-described preferable range, the natural oxide film on the metal surface is easily removed, and a hydroxyl group is easily imparted to the metal surface.

(Exposure)

As a method of exposing the surface of the substrate to the surface treatment agent, a method of applying a surface treatment agent (typically a surface treatment agent in a liquid state) which may contain a solvent to the surface of the substrate using a coating method such as a dipping method, a spin coating method, a roll coating method, or a doctor blade method and exposing the surface is an exemplary example.

The exposure temperature is, for example, 10° C. or higher and 90° C. or lower, preferably 20° C. or higher and 80° C. or lower, more preferably 20° C. or higher and 70° C. or lower, and still more preferably 20° C. or higher and 65° C. or lower.

From the viewpoint of selectively improving the hydrophobicity between two or more regions adjacent to each other and formed of materials that are different from each other on the surface of the substrate, the exposure time is preferably 20 seconds or longer, more preferably 30 seconds or longer, and still more preferably 45 seconds or longer.

The upper limit of the exposure time is not particularly limited, but is, for example, preferably 1 hour or shorter, more preferably 30 minutes or shorter, and still more preferably 15 minutes or shorter.

After the exposure, the surface may be washed (washed with water, an activator rinse, or the like) and/or dried (dried by nitrogen blow or the like) as necessary.

For example, as the washing treatment performed on the surface of the substrate having an inorganic pattern or an organic pattern using a washing liquid, a washing liquid of the related art which has been used for a washing treatment of an inorganic pattern or an organic pattern can be employed. Further, examples of the inorganic pattern include SPM (sulfuric acid/hydrogen peroxide water) and APM (ammonia/hydrogen peroxide water), and examples of the organic pattern include water and an activator rinse.

Further, the treated substrate after being dried may be additionally subjected to a heat treatment at 100° C. or higher and 300° C. or lower as necessary.

By exposing the surface, the compound (P) can be region-selectively adsorbed according to the material of each region on the surface of the substrate.

The contact angle of the surface of the substrate with water after the exposure to the surface treatment agent can be set to, for example, 60° or greater, preferably 80° or greater, and more preferably 85° or greater.

The upper limit of the contact angle is not particularly limited, but is, for example, 140° or less and typically 130° or less.

In the surface treatment method according to the present embodiment, since the materials of two or more proximity regions on the surface of the substrate are different from each other, it is possible to selectively improve the hydrophobicity between the two or more proximity regions and make the contact angles of water different from each other by exposing the surface.

The difference in contact angle of water between the two or more proximity regions is not particularly limited as long as the effects of the present invention are not impaired and is, for example, 10° or greater. From the viewpoint of selectively improving the hydrophobicity between the two or more proximity regions, the difference in contact angle of water is preferably 20° or greater, more preferably 30° or greater, and still more preferably 40° or greater.

The upper limit of the difference in contact angle is not particularly limited as long as the effects of the present invention are not impaired, and is, for example, 80° or less or 70° or less and typically 60° or less.

### Third Embodiment: Region Selective Film Formation Method for Substrate

Next, a region selective film formation method for a substrate using the surface treatment method according to the second embodiment will be described.

In the present embodiment, the region selective film formation method for the substrate includes treating the surface of the substrate using the surface treatment method according to the second embodiment and forming a film on the surface of the substrate, which has been subjected to the surface treatment, using an atomic layer deposition method (ALD method), in which the amount of the material of the film to be deposited region-selectively varies.

As a result of the surface treatment using the method according to the second embodiment, the contact angles (preferably the surface free energy) of water between the two or more regions are different from each other. In the present embodiment, the amounts of the material forming the film to be deposited between the two or more regions can be made to be region-selectively different from each other on the surface of the substrate.

Specifically, in a region where the contact angle of water between the two or more regions is larger (preferably, the surface free energy is smaller) than that of other regions, the film forming material according to the ALD method is unlikely to be adsorbed (preferably chemical adsorption) on the region on the surface of the substrate, and thus a difference in amount of the film forming material to be deposited is generated between the two or more regions. As a result, it is preferable that the amounts of the film forming material to be deposited on the substrate are region-selectively different from each other.

Examples of the chemical adsorption include chemical adsorption with a hydroxyl group.

Between the two or more regions, as a region where the contact angle of water tends to be greater (preferably, the surface free energy tends to be smaller) than that of other regions, a region containing at least one selected from the group consisting of W, Co, Al, Ni, Ru, and Cu is an exemplary example.

Among the two or more regions, as a region where the contact angle of water tends to be smaller (preferably, the surface free energy tends to be larger) than that of other regions, a region containing at least one selected from the group consisting of Si, Al₂O₃, SiN, Ox, TiN, TaN, Ge, SiGe, TEOS, a Low-k material, and ILD is an exemplary example.

(Film Formation According to ALD Method)

The film formation method according to the ALD method is not particularly limited, and a thin-film formation method carried out by adsorption (preferably chemical adsorption) using at least two gas phase reactants (hereinafter, simply referred to as “precursor gas”) is preferable.

Specifically, a method including the following steps (a) and (b) and repeating the following steps (a) and (b) at least once (one cycle) until a desired film thickness is obtained is an exemplary example.

The step (a) is a step of exposing the substrate subjected to the surface treatment by the method according to the second embodiment to a pulse of a first precursor gas; and the step (B) is a step of exposing the substrate to a pulse of a second precursor gas after the step (a).

The method may include a plasma treatment step and a step of removing or exhausting (purging) the first precursor gas and a reactant thereof with a carrier gas, the second precursor gas, or the like after the step (a) and before the step (b).

The method may or may not include a plasma treatment step and a step of removing or purging the second precursor gas and a reactant thereof with a carrier gas or the like after the step (b).

Examples of the carrier gas include an inert gas such as nitrogen gas, argon gas, or helium gas.

It is preferable that each pulse for each cycle and each layer to be formed are self-controlled and more preferable that each layer to be formed is a monoatomic layer.

The film thickness of the monoatomic layer can be set to be, for example, 5 nm or less, preferably 3 nm or less, more preferably 1 nm or less, and still more preferably 0.5 nm or less.

Examples of the first precursor gas include an organic metal, a metal halide, and a metal oxide halide, and specific examples thereof include tantalum pentaethoxide, tetrakis(dimethylamino) titanium, pentakis(dimethylamino) tantalum, tetrakis(dimethylamino) zirconium, tetrakis(dimethylamino) hafnium, tetrakis(dimethylamino) silane, copper hexafluoroacetylacetonate vinyltrimethylsilane, Zn(C₂H₅)₂, Zn(CH₃)₂, TMA (trimethylaluminum), TaCl₅, WF₆, WOCl₄, CuCl, ZrCl₄, AlCl₃, TiCl₄, SiCl₄, and HfCl₄.

Examples of the second precursor gas include a precursor gas capable of decomposing the first precursor and a precursor gas capable of removing the ligand of the first precursor, and specific examples thereof include H₂O, H₂O₂, O₂O₃, NH₃, H₂S, H₂Se, PH₃, AsH₃, C₂H₄, and Si₂H₆.

The exposure temperature in the step (a) is not particularly limited, but is, for example, 100° C. or higher and 800° C. or lower, preferably 150° C. or higher and 650° C. or lower, more preferably 180° C. or higher and 500° C. or lower, and still more preferably 200° C. or higher and 375° C. or lower.

The exposure temperature in the step (b) is not particularly limited and may be a temperature substantially equal to or higher than the exposure temperature in the step (a).

The film to be formed according to the ALD method is not particularly limited, and examples thereof include a film containing a pure element (such as Si, Cu, Ta, or W), a film containing an oxide (such as SiO₂, GeO₂, HfO₂, ZrO₂, Ta₂O₅, TiO₂, Al₂O₃, ZnO, SnO₂, Sb₂O₅, B₂O₃, In₂O₃, or WO₃), a film containing a nitride (such as Si₃N₄, TiN, AlN, BN, GaN, or NbN), a film containing a carbide (such as SiC), a film containing a sulfide (such as CdS, ZnS, MnS, WS₂, or PbS), a film containing a selenide (such as CdSe or ZnSe), a film containing a phosphide (GaP or InP), a film containing an arsenide (such as GaAs or InAs), and a mixture thereof.

### EXAMPLES

Hereinafter, the present invention will be described in more detail with reference to examples, but the present invention is not limited to these examples.

### Examples 1 to 25 and Comparative Examples 1 to 3

Octadecylphosphonic acid and the organic solvent (S) listed in Tables 1 and 2 were mixed, and the surface treatment agent of each example was prepared as a saturated solution at room temperature.

<Surface Treatment (1)>

The surface treatment of the W substrate was performed according to the following method using the obtained surface treatment agent of each example.

Pretreatment

The pretreatment was performed by immersing each substrate in a H₂O₂ aqueous solution having a concentration of 3.6% by mass at 25° C. for 1 minute. After the pretreatment, the substrate was washed with ion exchange distilled water for 1 minute. The substrate after being washed with water was dried by nitrogen stream.

Surface Treatment

The surface treatment was performed on the substrate by immersing each of the dried substrates in the surface treatment agent of each example under the surface treatment conditions listed in Tables 1 and 2. The surface-treated substrate was washed with isopropanol for 1 minute and further washed with ion exchange distilled water for 1 minute. The washed substrate was dried by nitrogen stream to obtain a surface-treated substrate.

<Measurement (1) of Contact Angle of Water>

The contact angle of water was measured for each substrate after the surface treatment described above.

The contact angle of water was measured by dropping pure water droplets (2.0 μL) on the surface of the surface-treated substrate using Dropmaster700 (manufactured by Kyowa Interface Science Co., Ltd.), and the contact angle obtained 2 seconds after the dropping of the droplets was used for the measurement. The results are listed in Tables 1 and 2.

TABLE 1

| | Organic solvent (S) | | | | | |
|---|---|---|---|---|---|---|
| | | Relative | Hansen | Contact angle (°) | | |
| | | dielectric | solubility | 60° C., 10 | 60° C., 1 | 40° C., 1 |
| | Type | constant | parameter dP | minutes | minute | minute |
| Reference | Water | 78.36 | 16 | 6.4 | — | — |
| Example 1 | | | | | | |
| Comparative | Propylene carbonate | 64.92 | 18 | 14.8 | — | — |
| Example 1 | | | | | | |
| Comparative | γ-Butyrolactone | 42.1 | 16.6 | 20.0 | — | — |
| Example 2 | | | | | | |
| Example 1 | Methanol | 33 | 12.3 | 92.2 | 63.7 | — |
| Comparative | Dimethylacetamide | 38.8 | 11.5 | 46.1 | — | — |
| Example 3 | | | | | | |
| Example 2 | BDG | 13.70 | 7 | 96.5 | — | — |
| Example 3 | PE | 12.71 | 6.3 | 93.1 | — | — |
| Example 4 | Benzyl alcohol | 12.70 | 6.3 | 84.0 | 61.9 | — |
| Example 5 | 2-Heptanone | 11.74 | 5.7 | 101.9 | 92.9 | 72.1 |
| Example 6 | Butyl glycol acetate | 8.66 | 5.5 | 97.3 | 87.4 | 67.1 |
| Example 7 | tert-Butyl alcohol | 12.5 | 5.1 | 91.7 | 76.6 | — |
| Example 8 | 1-Octanol | 10.21 | 5 | 96.5 | — | — |
| Example 9 | Benzotrifluoride | 9.18 | 8.8 | 101.4 | 95.7 | 92.9 |
| Example 10 | Decahydronaphthalene | 2.16 | 0 | 102.1 | 91.8 | 88.9 |
| Example 11 | Cyclohexane | 1.99 | 0 | 98.2 | 89.0 | 92 |
| Example 12 | Decane | <1 | 0 | 102.1 | 84.4 | 72.5 |

TABLE 2

| | Organic solvent (S) | | | | |
|---|---|---|---|---|---|
| | | Relative | Hansen | Contact angle (°) | |
| | | dielectric | solubility | 60° C., 10 | 60° C., 1 |
| | Type | constant | parameter dP | minutes | minute |
| Example 13 | Isobutyl alcohol | 18.22 | 5.7 | 92.1 | 73.9 |
| Example 14 | EL | 13.22 | 7.6 | 97.8 | 72.1 |
| Example 15 | Diethylene glycol | 15.76 | 7.8 | 79.7 | 45.5 |
| | monomethyl ether | | | | |
| Example 16 | 1-Nonanol | 9.13 | 4.8 | 95.6 | 82.7 |
| Example 17 | Toluene | 2.37 | 1.4 | 101.7 | 98.5 |
| Example 18 | PM | 9.40 | 5.6 | 75.6 | — |
| Example 19 | MIBC | 10.47 | 3.3 | 97.0 | — |
| Example 20 | 2,6-Dimethyl-4- | 2.98 | 3.1 | 91.4 | — |
| | heptanol | | | | |
| Example 21 | 2-Ethyl-1-butanol | 12.6 | 4.3 | 93.5 | — |
| Example 22 | 2-Butanone oxime | 2.9 | 4.9 | 71.3 | — |
| Example 23 | n-Dibutyl ether | 3.33 | 3.4 | 80.3 | — |
| Example 24 | Butyl acetate | 4.55 | 2.9 | 74.9 | — |
| Example 25 | 2,6-Dimethyl-4- | 9.82 | 3.7 | 90.0 | — |
| | heptanone | | | | |

In Tables 1 and 2, each abbreviation has the following meaning.

BDG: Diethylene glycol monobutyl ether

PE: Propylene glycol monomethyl ether

EL: Ethyl lactate

PM: Propylene glycol monomethyl ether acetate

MIBC: Methylisobutylcarbinol

As shown in the results listed in Tables 1 and 2, it was confirmed that the contact angle of the W substrate was able to be improved by 70° or greater under the surface treatment conditions of 60° C. or less for 10 minutes or shorter according to the surface treatment agents of Examples 1 to 25.

### Example 26

A surface treatment agent was prepared by mixing 0.05% by mass of octadecylphosphonic acid with propylene glycol monomethyl ether.

The surface treatment of the W substrate was performed according to the following method using the obtained surface treatment agent.

Pretreatment

The pretreatment was performed by immersing each substrate in a H₂O₂ aqueous solution having a concentration of 3.6% by mass at 25° C. for 1 minute. After the pretreatment, the substrate was washed with ion exchange distilled water for 1 minute. The substrate after being washed with water was dried by nitrogen stream.

Surface Treatment

The surface treatment was performed on the substrate by immersing each of the dried substrates in the surface treatment agent under the surface treatment conditions of 60° C. for 10 minutes. The surface-treated substrate was washed with isopropanol for 1 minute and further washed with ion exchange distilled water for 1 minute. The washed substrate was dried by nitrogen stream to obtain a surface-treated substrate.

### Example 27

The surface treatment was performed on the W substrate in the same manner as in Example 26 except that a H₅IO₆ aqueous solution having a concentration of 0.5% by mass was used in place of the H₂O₂ aqueous solution having a concentration of 3.6% by mass in the pretreatment.

### Comparative Example 4

The surface treatment was performed on the W substrate in the same manner as in Example 26 except that hydrofluoric acid having a concentration of 0.5% was used in place of the H₂O₂ aqueous solution having a concentration of 3.6% by mass in the pretreatment.

### Comparative Example 5

The surface treatment was performed on the W substrate in the same manner as in Example 26 except that the pretreatment was not performed. <Measurement (2) of contact angle of water>

The contact angle of water was measured in the same manner as in the section <Measurement (1) of contact angle of water> described above for each of the substrates after the surface treatments of Example 26, Example 27, Comparative Example 4, and Comparative Example 5. The results are listed in Table 3.

TABLE 3

| | | Contact |
|---|---|---|
| | Oxidizing agent for | angle |
| | pretreatment | (°) |
| Example 26 | 3.6% H₂O₂ | 67.1 |
| Example 27 | 0.5% H₅IO₆ | 64.5 |
| Comparative | 0.5% Hydrofluoric acid | 52.5 |
| Example 4 | | |
| Comparative | None | 32.7 |
| Example 5 | | |

As shown in the results listed in Table 3, it was confirmed that the contact angle of the W substrate was improved by 60° or greater under the surface treatment conditions of 60° C. for 10 minutes in Examples 26 and 27.

### Example 28

A surface treatment agent was prepared by mixing 0.05% by mass of octadecylphosphonic acid with benzyl alcohol.

The surface treatment was performed on the Ru substrate using the obtained surface treatment agent according to the following method.

Pretreatment

The pretreatment was performed by immersing each substrate in a H₅IO₆ aqueous solution having a concentration of 0.5% by mass at 25° C. for 1 minute. After the pretreatment, the substrate was washed with ion exchange distilled water for 1 minute. The substrate after being washed with water was dried by nitrogen stream.

Surface Treatment

The surface treatment was performed on the substrate by immersing each of the dried substrates in the surface treatment agent under the surface treatment conditions of 60° C. for 10 minutes. The surface-treated substrate was washed with isopropanol for 1 minute and further washed with ion exchange distilled water for 1 minute. The washed substrate was dried by nitrogen stream to obtain a surface-treated substrate.

### Comparative Example 6

The surface treatment was performed on the Ru substrate in the same manner as in Example 28 except that isopropanol was used in place of the H₅IO₆ aqueous solution having a concentration of 0.5% by mass in the pretreatment.

### Comparative Example 7

The surface treatment was performed on the Ru substrate in the same manner as in Example 28 except that hydrofluoric acid having a concentration of 0.5% was used in place of the H₅IO₆ aqueous solution having a concentration of 0.5% by mass in the pretreatment.

<Measurement (3) of Contact Angle of Water>

The contact angle of water was measured in the same manner as in the section <Measurement (1) of contact angle of water> described above for each of the substrates after the surface treatments of Example 28, Comparative Example 6, and Comparative Example 7. The results are listed in Table 4.

TABLE 4

| | | Contact |
|---|---|---|
| | Oxidizing agent for | angle |
| | pretreatment | (°) |
| Example 28 | 0.5% H₅IO₆ | 87.9 |
| Comparative | Isopropanol | 47.3 |
| Example 6 | | |
| Comparative | 0.5% Hydrofluoric acid | 50.7 |
| Example 7 | | |

As shown in the results listed in Table 4, it was confirmed that the contact angle of the Ru substrate was improved by 85° or greater under the surface treatment conditions of 60° C. for 10 minutes in Example 28.

### Test Example 1-1

The pretreatment was performed by immersing the W substrate in a H₂O₂ aqueous solution having a concentration of 3.6% by mass at 25° C. for 1 minute. After the pretreatment, the substrate was washed with ion exchange distilled water for 1 minute. The substrate after being washed with water was dried by nitrogen stream.

### Test Example 1-2

The surface treatment was performed on the substrate in the same manner as in Test Example 1-1 except that a H₅IO₆ aqueous solution having a concentration of 0.5% by mass was used in place of the H₂O₂ aqueous solution having a concentration of 3.6% by mass in Test Example 1-1.

### Test Example 1-3

The surface treatment was performed on the substrate in the same manner as in Test Example 1-1 except that hydrofluoric acid having a concentration of 0.5% was used in place of the H₂O₂ aqueous solution having a concentration of 3.6% by mass in Test Example 1-1.

(Analysis of Surface State of Substrate)

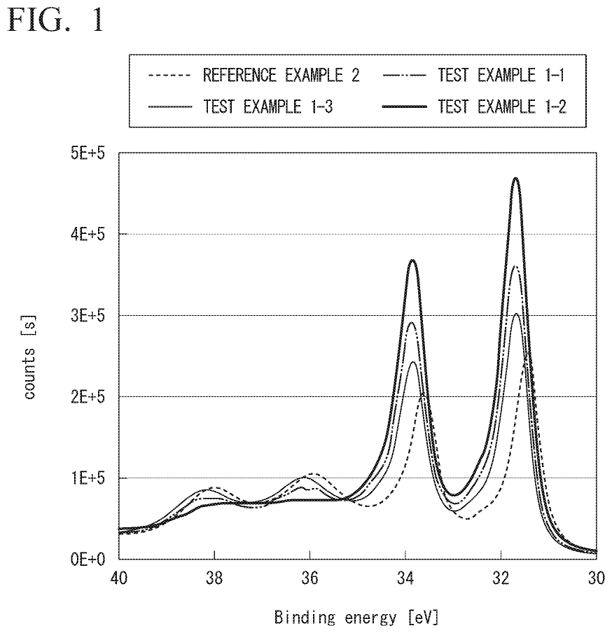

The surface states of the substrates of Test Examples 1-1 to 1-3 and the untreated W substrate (Reference Example 2) were analyzed by X-ray photoelectron spectroscopy (XPS). The analysis results are shown in FIG. 1.

As shown in the results in FIG. 1, it was confirmed that W and WO₃ were present in the untreated substrate of Reference Example 2.

Meanwhile, it was confirmed that the amount of WO₃ was decreased in the substrates after the surface treatment (pretreatment) of Test Examples 1-1 and 1-2.

Further, it was confirmed that the change in WO₃ was extremely small in the substrate after the surface treatment (pretreatment) of Test Example 1-3.

### Test Example 2-1

The surface treatment was performed by immersing a SiO₂ substrate or an Al₂O₃ substrate in a H₂O₂ aqueous solution having a concentration of 3.6% by mass at 25° C. for 1 minute. After the pretreatment, the substrate was washed with ion exchange distilled water for 1 minute. The substrate after being washed with water was dried by nitrogen stream.

### Test Example 2-2

The surface treatment was performed on the substrate in the same manner as in Test Example 2-1 except that a H₅IO₆ aqueous solution having a concentration of 0.5% by mass was used in place of the H₂O₂ aqueous solution having a concentration of 3.6% by mass in Test Example 2-1.

### Test Example 2-3

The surface treatment was performed on the substrate in the same manner as in Test Example 2-1 except that hydrofluoric acid having a concentration of 0.5% was used in place of the H₂O₂ aqueous solution having a concentration of 3.6% by mass in Test Example 2-1.

(Evaluation of Damage to Substrate Due to Pretreatment)

The amount of film loss (etching amount) after immersion of each substrate which had been subjected to the surface treatment of Test Examples 2-1, 2-2, and 2-3 at 25° C. for 15 minutes was measured by sheet resistance. The sheet resistance was measured using a resistivity measuring device VR-250 (manufactured by Kokusai Electric Semiconductor Service Inc.). The results are listed in Table 5.

TABLE 5

| | |
|---|---|
| | Etching loss |
| Oxidizing agent for | [Å] |

| | pretreatment | SiO₂ | Al₂O₃ |
|---|---|---|---|
| Test | 3.6% H₂O₂ | <1 | <1 |
| Example 2-1 | | | |
| Test | 0.5% H₅IO₆ | <1 | <1 |
| Example 2-2 | | | |
| Test | 0.5% Hydrofluoric acid | 3.3 | 38.1 |
| Example 2-3 | | | |

As shown in the results listed in Table 5, it was confirmed that the SiO₂ substrate and the Al₂O₃ substrate were hardly dissolved by the surface treatment (pretreatment) in Test Examples 2-1 and 2-2.

While preferred embodiments of the invention have been described and illustrated above, it should be understood that these are exemplary of the invention and are not to be considered as limiting. Additions, omissions, substitutions, and other modifications can be made without departing from the scope of the invention. Accordingly, the invention is not to be considered as being limited by the foregoing description and is only limited by the scope of the appended claims.

What is claimed is:

1. A surface treatment agent used for treating a substrate having a surface that has two or more regions made of different materials, in which at least one of the two or more regions has a metal surface, and pretreated with an oxidizing agent, the agent comprising:
a compound (P) represented by Formula (P-1); and
an organic solvent (S) having a relative dielectric constant of 35 or less:
R¹—P(═O)(OR²)(OR³) (P-1)
wherein R¹ represents a linear or branched alkyl group, a linear or branched fluorinated alkyl group, or an aromatic hydrocarbon group which may have a substituent, and R² and R³ each independently represent a hydrogen atom, a linear or branched alkyl group, a linear or branched fluorinated alkyl group, or an aromatic hydrocarbon group which may have a substituent.

2. The surface treatment agent according to claim 1, wherein the metal surface contains at least one selected from the group consisting of tungsten, ruthenium, copper, and cobalt.

3. The surface treatment agent according to claim 2, wherein the metal surface contains at least one selected from the group consisting of tungsten and ruthenium.

4. The surface treatment agent according to claim 1, wherein the oxidizing agent contains at least one selected from the group consisting of hydrogen peroxide and perhalogen acid.

5. A surface treatment method for a substrate having a surface that has two or more regions made of different materials, in which at least one region of the two or more regions has a metal surface, the method comprising:
performing a pretreatment on the surface with an oxidizing agent; and
exposing the pretreated surface to the surface treatment agent according to claim 1.

6. A region selective film formation method for a surface of a substrate, the method comprising:
treating the surface of the substrate using the surface treatment method according to claim 5; and
forming a film on the surface of the substrate which has been subjected to the surface treatment using an atomic layer deposition method,
wherein an amount of a material of the film to be deposited varies in a region-selective manner.
